(19) United States
(12) Patent Application Publication
(10) Pub. No.: US 2023/0057756 A1
(43) Pub. Date: Feb. 23, 2023

(54) Crossbar Mapping Of DNN Weights

(71) Applicant: THE REGENTS OF THE UNIVERSITY OF MICHIGAN, Ann Arbor, MI (US)

(72) Inventors: Zhengya ZHANG, Ann Arbor, MI (US); Wei TANG, Fremont, CA (US)

(73) Assignee: THE REGENTS OF THE UNIVERSITY OF MICHIGAN, Ann Arbor, MI (US)

(21) Appl. No.: 17/888,014

(22) Filed: Aug. 15, 2022

Related U.S. Application Data
(60) Provisional application No. 63/234,486, filed on Aug. 18, 2021.

(51) Int. Cl. G11C 11/54; G06N 20/10; G06N 3/063; G11C 13/00; G06F 7/544

(52) U.S. Cl. CPC G11C 11/54; G06N 20/10; G06N 3/063; G11C 13/004; G06F 7/5443; G11C 2213/77

(57) ABSTRACT

A method is presented for mapping weights for kernels of a neural network onto a crossbar array. In one example, the crossbar array is comprised of an array of non-volatile memory cells arranged in columns and rows, such that memory cells in each row of the array is interconnected by a respective drive line and each column of the array is interconnected by a respective bit line; and wherein each memory cell is configured to receive an input signal indicative of a multiplier and operates to output a product of the multiplier and a weight of the given memory cell onto the corresponding bit line of the given memory cell, where the value of the multiplier is encoded in the input signal and the weight of the given memory cell is stored by the given memory cell.

### CROSS-REFERENCE TO RELATED APPLICATIONS

This application claims the benefit of U.S. Provisional Application No. 63/234,486 filed on Aug. 18, 2021. The entire disclosure of the above application is incorporated herein by reference.

### FIELD

The present disclosure relates to a computing system architecture and more specifically to a technique for mapping kernel weights of a neural network into a crossbar array.

### BACKGROUND

Machine learning or artificial intelligence (AI) tasks use neural networks to learn and then to infer. The workhorse of many types of neural networks is vector-matrix multiplication—computation between an input and weight matrix. Learning refers to the process of tuning the weight values by training the network on vast amounts of data. Inference refers to the process of presenting the network with new data for classification.

Crossbar arrays perform analog vector-matrix multiplication naturally. Each row and column of the crossbar is connected through a processing element (PE) that represents a weight in a weight matrix. Inputs are applied to the rows as voltage pulses and the resulting column currents are scaled, or multiplied, by the PEs according to physics. The total current in a column is the summation of each PE current.

To improve computational efficiency, it is desirable to map the weights of one or more kernels of a neural network onto a crossbar array. This section provides background information related to the present disclosure which is not necessarily prior art.

### SUMMARY

This section provides a general summary of the disclosure, and is not a comprehensive disclosure of its full scope or all of its features.

A method is presented for mapping weights for kernels of a neural network onto a crossbar array. In one example, the crossbar array is comprised of an array of non-volatile memory cells arranged in columns and rows, such that memory cells in each row of the array is interconnected by a respective drive line and each column of the array is interconnected by a respective bit line; and wherein each memory cell is configured to receive an input signal indicative of a multiplier and operates to output a product of the multiplier and a weight of the given memory cell onto the corresponding bit line of the given memory cell, where the value of the multiplier is encoded in the input signal and the weight of the given memory cell is stored by the given memory cell.

The method includes: receiving two or more kernels of a neural network, where each kernel is represented as values in a matrix; for each kernel of the two or more kernels, converting the matrix into a column vector; for each kernel of the two or more kernels, mapping a corresponding column vector to a column of a crossbar array, and storing values for each kernel of the two or more kernels in the array of non-volatile memory cells.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 depicts an architecture for a computing system.

FIG. 2 is a diagram illustrating an example implementation for a crossbar module.

FIG. 3 illustrates a technique for mapping weights for kernels of a neural network onto a crossbar array.

FIGS. 4A and 4B further illustrate how the kernels are mapped onto a crossbar array.

FIG. 4C illustrates how two or more kernels are mapped onto a crossbar array.

FIG. 5 illustrates how to process an input using the crossbar array.

FIG. 6 illustrates how to map kernels with two or more channels onto a crossbar array.

Corresponding reference numerals indicate corresponding parts throughout the several views of the drawings.

### DETAILED DESCRIPTION

Example embodiments will now be described more fully with reference to the accompanying drawings.

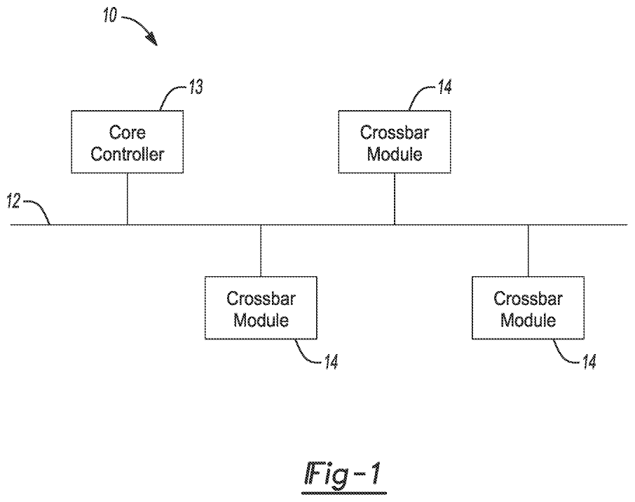

FIG. 1 depicts an example architecture for a computing system 10. The computing system 10 includes: a data bus 12; a core controller 13 and a plurality of crossbar modules 14. The core controller 13 is interfaced with or connected to the data bus 12. Likewise, each of the crossbar modules 14 are interfaced with or connected to the data bus. In an example embodiment, the data bus is further defined as an advanced extensible interface (AXI). It is readily understood that the computing system 10 can be implemented with other types of data buses.

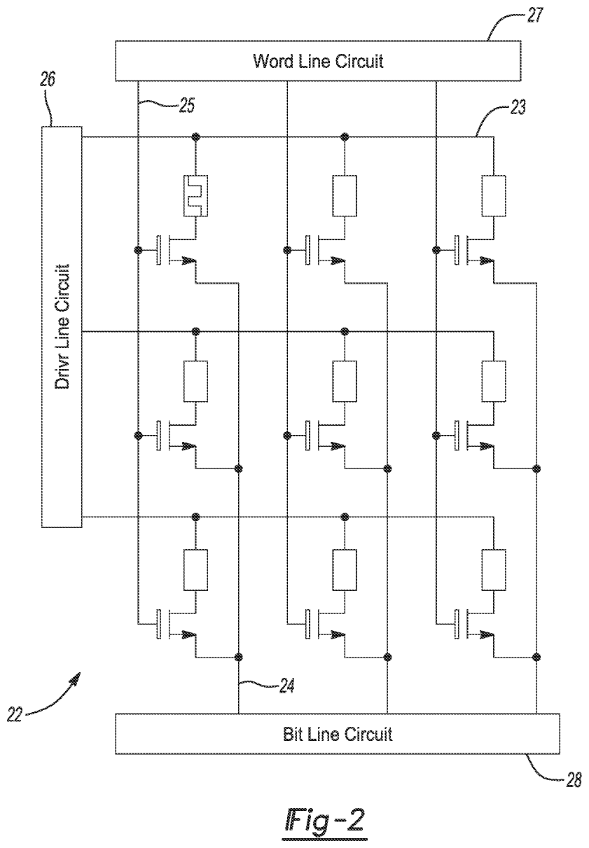

FIG. 2 further illustrates an example implementation for the crossbar modules 14. Each crossbar module 14 is comprised of an array of non-volatile memory cells 22. The array of memory cells 22 is arranged in columns and rows and commonly referred to as a crossbar array. The memory cells 22 in each row of the array are interconnected by a respective drive line 23; whereas, the memory cells 22 in each column of the array are interconnected by a respective bit line 24. One example embodiment for a memory cell 22 is a resistive random-access memory (i.e., memristor) in series with a transistor as shown in FIG. 2. Other implementations for a given memory cell are envisioned by this disclosure.

In the example embodiment, the computing system 10 employs an analog approach where an analog value is stored in the memristor of each memory cell. In an alternative embodiment, the computing system 10 may employ a digital approach, where a binary value is stored in the memory cells. For a binary number comprised of multiple bits, the memory cells are grouped into groups of memory cells, such that the value of each bit in the binary number is stored in a different memory cell within the group of memory cells. For example, a value for each bit in a five bit binary number is stored in a group of five adjacent columns of the array, where the value for the most significant bit is stored in memory cell on the leftmost column of a group and the value for the least significant bit is stored in memory cell in the rightmost column of a group. In this way, a multiplicand of a multiply-accumulate operation is a binary number comprised of multiple bits and stored across a one group of memory cells in the array. It is readily understood that the number of columns in a given group of memory cells may be more or less depending on the number of bits in the binary number.

During operation, each memory cell 22 in a given group of memory cells is configured to receive an input signal indicative of a multiplier and operates to output a product of the multiplier and the value stored in the given memory cell onto the corresponding bit line connected to the given memory cell. The value of the multiplier is encoded in the input signal.

Dedicated mixed-signal peripheral hardware is interfaced with the rows and columns of the crossbar arrays. The peripheral hardware supports read and write operations in relation to the memory cells which comprise the crossbar array. Specifically, the peripheral hardware includes a drive line circuit 26, a wordline circuit 27 and a bitline circuit 28. Each of these hardware components may be designed to minimize the number of switches and level-shifters needed for mixing high-voltage and low-voltage operation as well as to minimize the total number of switches.

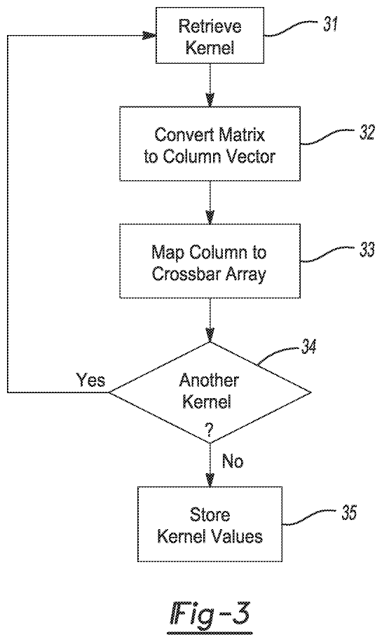

FIG. 3 illustrates a technique for mapping weights for kernels of a neural network onto a crossbar array. The neural network may be comprised of two or more kernels, where weights of each kernel is represented as values in a matrix. As a starting point, a kernel of the neural network is retrieved at 31.

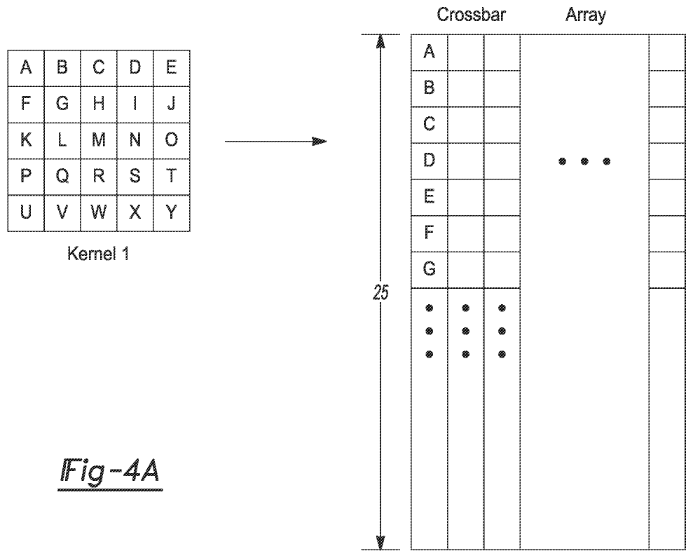

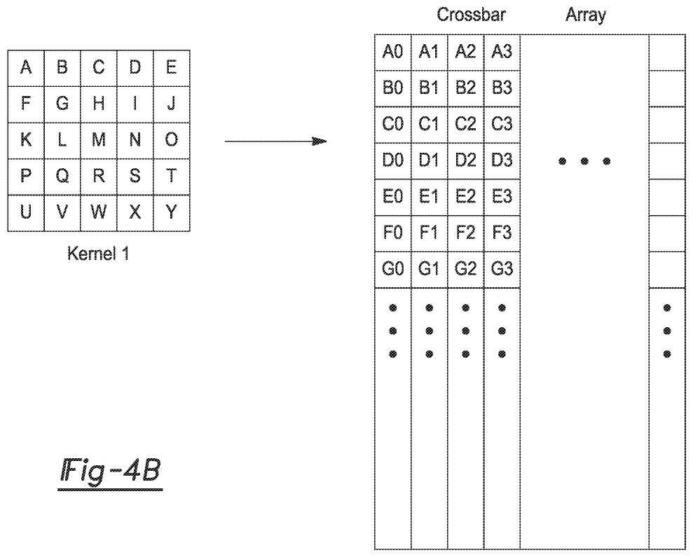

For each kernel, the matrix representing a given kernel is converted into a column vector as indicated at 32 and then mapped to a column of the crossbar array as indicated at 33. For illustration purposes, kernel 1 is a 5 by 5 matrix, where the values of the matrix are mapped to column 1 of the crossbar array as seen in FIG. 4A. The number of rows in the crossbar array corresponds to the number of values in the kernel. In this example, the 5 by 5 matrix maps to the 25 rows in column 1 of the crossbar array. In some embodiments, the kernel weights may include negative values. In this case, kernel weights ranging from −2^{(x-1)} to +2^{(x-1)}−1 is offset by 2^{(x-1)} to a positive value that can be stored in the crossbar array.

Additional kernels are in turn mapped to successive columns of the crossbar array. That is, kernel 2 is mapped to column 2, kernel 3 is mapped to column 3 and so forth. It is understood that the crossbar array can be sized to accommodate the size of the kernels in the neural network.

In some embodiments, the values in the kernel matrix are represented as binary numbers having two or more bits. For illustration purposes, values in kernel 1 are represented by four bit binary number that are mapped into a rectangular array (25×4 array) of the crossbar array as shown in FIG. 4B. That is, each row in the rectangular array corresponds to a different value in the matrix and each column in the rectangular array corresponds to a bit of the binary number used to represent the value. It is readily understood that the values in the kernel matrix can be represented by binary numbers having more or less bits.

Returning to FIG. 3, another kernel is retrieved and mapped into the crossbar array until all of the kernels have been mapped to the crossbar array as indicated at 34. Kernels are mapped to different columns (or groups of columns) as seen in FIG. 4C. That is, kernel 1 is mapped to the left most column, kernel 2 is mapped to the second left most column and so forth. The kernel values are then stored in the corresponding memory cells comprising the crossbar array.

During execution, an input is fed into a neural network, such as a deep neural network. The layers of the neural network are implemented by a crossbar array using the mapping technique described above. For a given input, multiply accumulate operations are performed for each layer of the neural network and output from the multiply accumulate operations are post-processed and passed on to the next layer of the neural network.

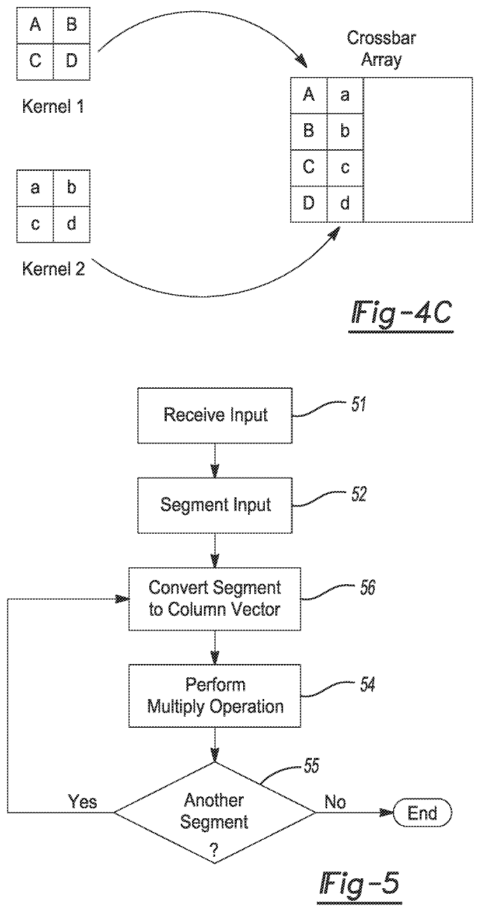

In one example, the input represents an image (e.g., 28 pixels by 28 pixels or 244 pixels by 244 pixels). Referring to FIG. 5, the image may be segmented at 52 into a plurality of segments, where each segment is a matrix having the same number of rows and the same number of columns as the kernel. Continuing with the example above, each segment is a 5 by 5 matrix. For each segment, the input segments are converted at 56 into column vectors in preparation for multiply accumulate operations. The column vector is in turn presented to the crossbar array for the multiply accumulate operation as indicated at 54. The multiply accumulate operation is reformulated as 0ₖ=Σᵢ^{N}^{_{rows}}Iᵢ(W_{i,k}−2^{(x-1)})=Σᵢ^{N}^{_{rows}}IᵢW_{i,k}−2^{(x-1)}ΣIᵢ, where 2^{(x-1)}ΣIᵢ is a bias term. The bias term may be implemented by adding an extra crossbar column with cell values of 1. The partial-sum results of the splitting columns and bias column are shifted and added to a complete summation result, which is done by the peripheral hardware of the crossbar array.

To implement a neural network with multiple layers, each layer may be mapped onto a different crossbar array. For example, a first layer is mapped to a first crossbar array and a second layer is mapped to a second crossbar array. Outputs of one crossbar array are digitized and fed into the next crossbar array. In some cases, kernel dimensions and/or the number of kernels in one layer may be too large to fit onto one crossbar array. In such cases, multiple crossbar arrays may be used, such that partial outputs of each crossbar are digitized and then assembled together before being fed to other layers of a neural network.

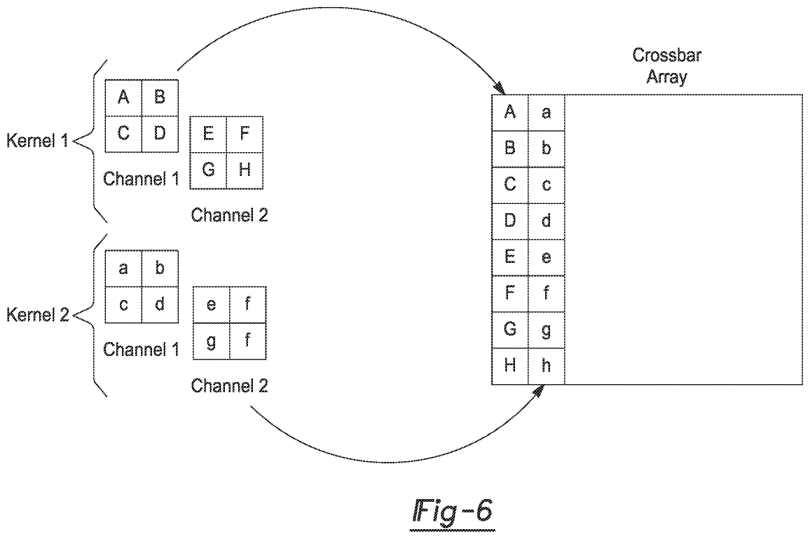

In some embodiments, the input may be comprised of two or more channels. For example, a color image has three channels: one for red, one for green and one for blue. In this case, the kernel values for the second channel of the first kernel are mapped to the same column as the kernel values for the first channel of the first kernel. Specifically, the kernel values for the second channel are insert below the kernel values for the first channel as shown in FIG. 6. Likewise, kernel values for the second channel of the second kernel are mapped to the same column as the kernel values for the first channel of the second kernel. It is understood that kernel values for additional channels can be appended to the bottom of the kernel values in a given column.

The system described herein may be implemented by one or more computer programs executed by one or more processors. The computer programs include processor-executable instructions that are stored on a non-transitory tangible computer readable medium. The computer programs may also include stored data. Non-limiting examples of the non-transitory tangible computer readable medium are nonvolatile memory, magnetic storage, and optical storage.

Some portions of the above description present the techniques described herein in terms of algorithms and symbolic representations of operations on information. These algorithmic descriptions and representations are the means used by those skilled in the data processing arts to most effectively convey the substance of their work to others skilled in the art. These operations, while described functionally or logically, are understood to be implemented by computer programs. Furthermore, it has also proven convenient at times to refer to these arrangements of operations as modules or by functional names, without loss of generality.

Unless specifically stated otherwise as apparent from the above discussion, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system memories or registers or other such information storage, transmission or display devices.

Certain aspects of the described techniques include process steps and instructions described herein in the form of an algorithm. It should be noted that the described process steps and instructions could be embodied in software, firmware or hardware, and when embodied in software, could be downloaded to reside on and be operated from different platforms used by real time network operating systems.

The present disclosure also relates to an apparatus for performing the operations herein. This apparatus may be specially constructed for the required purposes, or it may comprise a computer selectively activated or reconfigured by a computer program stored on a computer readable medium that can be accessed by the computer. Such a computer program may be stored in a tangible computer readable storage medium, such as, but is not limited to, any type of disk including floppy disks, optical disks, CD-ROMs, magnetic-optical disks, read-only memories (ROMs), random access memories (RAMs), EPROMs, EEPROMs, magnetic or optical cards, application specific integrated circuits (ASICs), or any type of media suitable for storing electronic instructions, and each coupled to a computer system bus. Furthermore, the computers referred to in the specification may include a single processor or may be architectures employing multiple processor designs for increased computing capability.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A method for mapping weights for kernels of a neural network onto a crossbar array, comprising:
receiving two or more kernels of a neural network, where each kernel is represented as values in a matrix;
for each kernel of the two or more kernels, converting the kernel into a column vector;
for each kernel of the two or more kernels, mapping a corresponding column vector to a column of a crossbar array, wherein the crossbar array is comprised of an array of non-volatile memory cells arranged in columns and rows, such that memory cells in each row of the array is interconnected by a respective drive line and each column of the array is interconnected by a respective bit line; and wherein each memory cell is configured to receive an input signal indicative of a multiplier and operates to output a product of the multiplier and a weight of the given memory cell onto the corresponding bit line of the given memory cell, where the value of the multiplier is encoded in the input signal and the weight of the given memory cell is stored by the given memory cell; and
storing values for each kernel of the two or more kernels in the array of non-volatile memory cells.

2. The method of claim 1 further comprises, for each kernel of the two or more kernels, mapping the column vector for each kernel in successive columns of the crossbar array.

3. The method of claim 1 further comprises, for each kernel of the two or more kernels, converting the matrix into a rectangular array, where the values in the matrix of a given kernel are represented by a binary number having at least two bits, each row in the rectangular array corresponds to a different value in the matrix and each column in the rectangular array corresponds to a bit of the binary number used to represent the value.

4. The method of claim 1 further comprises, for each kernel of the two or more kernels, converting the matrix into a rectangular array, where the values in the matrix of a given kernel are represented by a binary number having at least two bits, each row in the rectangular array corresponds to a different value in the matrix, and each column in the rectangular array corresponds to a subset of bits of the binary number used to represent the value.

5. The method of claim 1 further comprises receiving an input representing an image and performing a multiply accumulate operation in relation to each of the two or more kernels stored in the crossbar array, where the input is a matrix having same number of rows and same number of columns as a given kernel of the two or more kernels.

6. The method of claim 5 further comprises adding an additional column to the array of non-volatile memory cells, where the additional column stores a bias term for the multiply accumulate operation.

7. The method of claim 1 further comprises
receiving an input representing an image;
segmenting the input into segments, where each segment is a matrix having same number of rows and same number of columns as a given kernel of the two or more kernels; and
for each segment, performing a multiply accumulate operation in relation to each of the two or more kernels stored in the crossbar array.

8. The method of claim 1 wherein each memory cell is further defined as a resistive random-access memory.

9. A method for mapping weights for kernels of a neural network onto a crossbar array, comprising:
receiving two or more kernels of a neural network, where each kernel is represented as values in a matrix;
for each kernel of the two or more kernels, converting the kernel into a rectangular array, where the values in the matrix of a given kernel are represented by a binary number having at least two bits, each row in the rectangular array corresponds to a different value in the matrix and each column in the rectangular array corresponds to a bit of the binary number used to represent the value;
for each kernel of the two or more kernels, mapping a corresponding rectangular array to a subset of columns in a crossbar array, wherein the crossbar array is comprised of an array of non-volatile memory cells arranged in columns and rows, such that memory cells in each row of the array is interconnected by a respective drive line and each column of the array is interconnected by a respective bit line; and wherein each memory cell is configured to receive an input signal indicative of a multiplier and operates to output a product of the multiplier and a weight of the given memory cell onto the corresponding bit line of the given memory cell, where the value of the multiplier is encoded in the input signal and the weight of the given memory cell is stored by the given memory cell; and
storing values for each kernel of the two or more kernels in accordance with the mapping into the array of non-volatile memory cells.

10. The method of claim 9 further comprises receiving an input representing an image and performing a multiply accumulate operation in relation to each of the two or more kernels stored in the crossbar array, where the input is a matrix having same number of rows and same number of columns as a given kernel of the two or more kernels.

11. The method of claim 10 further comprises adding an additional column to the array of non-volatile memory cells, where the additional column stores a bias term for the multiply accumulate operation.

12. The method of claim 9 further comprises
receiving an input representing an image;
segmenting the input into segments, where each segment is a matrix having same number of rows and same number of columns as a given kernel of the two or more kernels; and
for each segment, performing a multiply accumulate operation in relation to each of the two or more kernels stored in the crossbar array.

13. The method of claim 9 wherein each memory cell is further defined as a resistive random-access memory.

14. A method for mapping weights for kernels of a neural network onto a crossbar array, comprising:
receiving two or more kernels of a neural network, where each kernel is represented as values in a matrix;
for each kernel of the two or more kernels, converting the kernel into a column vector;
for each kernel of the two or more kernels, mapping a corresponding column vector to a column of a crossbar array, wherein the crossbar array is comprised of an array of non-volatile memory cells arranged in columns and rows, such that memory cells in each row of the array is interconnected by a respective drive line and each column of the array is interconnected by a respective bit line; and wherein each memory cell is configured to receive an input signal indicative of a multiplier and operates to output a product of the multiplier and a weight of the given memory cell onto the corresponding bit line of the given memory cell, where the value of the multiplier is encoded in the input signal and the weight of the given memory cell is stored by the given memory cell;
storing values for each kernel of the two or more kernels in accordance with the mapping into the array of non-volatile memory cells;
receiving an input representing an image; and
performing a multiply accumulate operation in relation to each of the two or more kernels stored in the crossbar array, where the input is a matrix having same number of rows and same number of columns as a given kernel of the two or more kernels.

15. The method of claim 14 further comprises, for each kernel of the two or more kernels, mapping the column vector for each kernel in successive columns of the crossbar array.

16. The method of claim 14 further comprises adding an additional column to the array of non-volatile memory cells, where the additional column stores a bias term for the multiply accumulate operation.

17. The method of claim 14 wherein each memory cell is further defined as a resistive random-access memory.
